(19) United States
(12) Patent Application Publication
(10) Pub. No.: US 2025/0254799 A1
(43) Pub. Date: Aug. 7, 2025

(54) MULTI-LAYER BOARD MANUFACTURING DEVICE AND MULTI-LAYER BOARD OPERATING PLATFORM

(71) Applicant: FIND HOW ENTERPRISE CO. LTD., Taipei (TW)

(72) Inventors: KUO-CHING YEH, Taipei (TW); SHIH-HAO YEH, Taipei (TW)

(21) Appl. No.: 18/890,851

(22) Filed: Sep. 20, 2024

(30) Foreign Application Priority Data
Feb. 1, 2024 (TW) 113104050

(51) Int. Cl. H05K 3/46

(52) U.S. Cl. CPC H05K 3/46; H05K 2203/0195

(57) ABSTRACT

The present application provides a multi-layer board operating platform adapted to be configured on a slide slidable on a base. The multi-layer board operating platform includes a casing body having an upper surface, wherein the upper surface has a plurality of openings; a positioning pin structure configured in the casing body and comprising a plurality of positioning pins capable of telescopically passing through the plurality of openings, respectively; and a driving device configured in the case body and adjacent to the positioning pin structure for driving an elevation of at least one of the plurality of positioning pins.

### CROSS-REFERENCE TO RELATED APPLICATION AND CLAIM OF PRIORITY

This application claims the benefit of Taiwan Patent Application No. 113104050, filed on Feb. 1, 2024, at the Taiwan Intellectual Property Office, the disclosures of which are incorporated herein in their entirety by reference.

### FIELD OF THE INVENTION

The present invention relates to a multi-layer board manufacturing device, particularly to a multi-layer board manufacturing device including a minimized multi-layer board operating platform that can be translatably located at one of a plurality of areas.

### BACKGROUND OF THE INVENTION

Print Circuit Board (PCB) is a circuit board having a pattern made by wiring circuit parts according to circuit design and manufactured by surface treatment and mechanical processing. The PCB can be designed into a multi-layer PCB according to the complex functions of electronic devices. In a manufacturing procedure of the multi-layer PCB, a lamination process is needed. The lamination process of the multi-layer PCB includes a layer stack-up step of stacking copper foil sheets, insulation layers (e.g., prepreg (PP)), inner layers in a proper order to form “board multi-layers” for lamination; and a lamination step for laminating the stacked board multi-layers together by applying high temperature and high pressure to form “the multi-layer board”. The multi-layer board forms the multi-layer PCB through further processes such as drilling, depositing, plating, etching, etc.

During the forming process of the board multi-layers, due to dust or impurities carried on the insulation layer itself, or dust or residues (such as resin particles) remaining on the insulation layer caused by its cutting process or positioning hole production process, the formed board multi-layers including these insulation layers usually carry lots of micro-particles. If no precaution is taken, these micro-particles may easily contaminate the contact surface between a copper foil sheet and a steel plate during the arrangements thereof, thus causing pits and dents (PND) on the surfaces of the copper foil sheets after the lamination process. After the subsequent etching process, these defects may cause short circuit, open circuit or noise of surface circuits of circuit boards, which cause a low process yield of circuit boards.

Furthermore, there are liftable positioning pins in an operating platform of the multi-layer board in the art, to assist the positioning of each layer. The positioning pins in the art are lifted by a large reducer motor underneath the operating platform, which causes the operating platform to be too large to be conveniently moved and must be fixed at an area. Thus, all workpieces, such as all materials of the layers, the steel plate, etc., during the lamination process are all stacked-up at the same area. Because the PP layers of the multi-later board need to be drilled during the manufacturing procedure of the multi-layer PCB, PP dust or impurities will be produced. If the layer stack-up step and the lamination step of the lamination process are done in the same area, the whole environment of the area will be contaminated by the PP dust or impurities, and the cleanliness of the contact surface between the copper foil sheet and the steel plate cannot be kept. The short circuit, open circuit or noise of surface circuits of circuit boards may occur due to the PP dust or impurities remaining between the copper foil sheet and the steel plate.

China Patent No. CN 1416312A discloses a method for manufacturing multi-layer PCBs. In order to prevent the contact surface between a copper foil sheet and a steel plate from being contaminated by micro-particles from insulation layers, the method comprises (1) arranging two sheets of copper foil on upper and lower surfaces of a steel plate in a clean room environment, and fixing the three pieces with a clamp to form a combination of the steel plate and copper foil sheets; and (2) moving these combinations to a general working environment for formal stacking and assembly process together with board multi-layers including insulation layers. However, once these combinations of steel plates and copper foil sheets are moved, there would be a problem in that it is hard to precisely align the layers.

In view of the above, because of the defects in the prior art, the inventors have provided the present invention to effectively overcome the disadvantages of the prior art. The descriptions of the present invention are as follows:

### SUMMARY OF EXEMPLARY EMBODIMENTS

To solve the aforementioned problems, an operating platform that is lightweight, minimized and translatable to be located at different areas is needed for forming the board multi-layers. The operating platform is configured on a base, and uses at least one thin motor to control an elevation of a plurality of positioning pins in a multi-axis synchronous inching manner, wherein the at least one thin motor can be powered by a battery or connected to a power source using a power cord. Therefore, the size of the multi-layer board operating platform is reduced. Because of the small size and the light weight of the multi-layer board operating platform, it can be configured on a slide to be translated on the base and be located at different areas to form a multi-layer board manufacturing device of the present invention.

One object of this application is to provide a multi-layer board manufacturing device. The multi-layer board manufacturing device includes a base having a first end and a second end; a slide configured on the base; and a multi-layer board operating platform configured on the slide to translate between the first end and the second end. The multi-layer board operating platform includes: a casing body having an upper surface, wherein the upper surface has a plurality of openings; a positioning pin structure configured in the casing body and having a plurality of positioning pins, wherein the plurality of positioning pins respectively correspond to the plurality of openings and are capable of telescopically sticking out from the plurality of openings; at least one DC driving device configured in the casing body and adjacent to the positioning pin structure for driving an elevation of the positioning pin structure; and a controller configured in the casing body and electrically connected to the at least one DC driving device for controlling the at least one DC driving device to simultaneously drive a synchronized elevation of the positioning pin structure.

Another object of the present invention is to provide a multi-layer board operating platform, wherein the multi-layer board operating platform is to be configured on a slide of a base to translate on the base. The multi-layer board operating platform includes: a casing body; a first layer board configured on the casing body and having a plurality of openings; a positioning pin structure configured in the casing body and comprising a plurality of positioning pins, wherein the plurality of positioning pins are capable of telescopically passing through the plurality of openings, respectively; and at least one DC driving device configured adjacent to the positioning pin structure for driving an elevation of the positioning pin structure.

Another object of the present invention is to provide a multi-layer board operating platform adapted to be configured on a slide slidable on a base. The multi-layer board operating platform includes: a casing body having an upper surface, wherein the upper surface has a plurality of openings; a positioning pin structure configured in the casing body and comprising a plurality of positioning pins capable of telescopically passing through the plurality of openings, respectively; and a driving device configured in the case body and adjacent to the positioning pin structure for driving an elevation of at least one of the plurality of positioning pins.

### BRIEF DESCRIPTION OF THE DRAWINGS

The embodiments and advantages of the present invention will become more readily apparent to those ordinarily skilled in the art after reviewing the following detailed descriptions and accompanying drawings.

FIG. 1 shows a schematic diagram of a multi-layer board manufacturing device according to an embodiment of the present invention.

FIG. 2 shows an exploded schematic diagram of a slide of the multi-layer board manufacturing device according to the embodiment of the present invention.

FIG. 3 shows an exploded schematic diagram of a multi-layer board operating platform of the multi-layer board manufacturing device according to the embodiment of the present invention.

FIG. 4 shows a perspective schematic diagram of the multi-layer board operating platform of FIG. 3.

FIG. 5 shows a schematic diagram of a positioning pin structure of a multi-layer board operating platform according to a second embodiment of the present invention.

FIG. 6 shows a schematic diagram of a positioning pin structure of a multi-layer board operating platform according to a third embodiment of the present invention.

### DETAILED DESCRIPTION OF THE PREFERRED EMBODIMENTS

The present invention will now be described more specifically with reference to the following embodiments. It is to be noted that the following descriptions of preferred embodiments of this invention are presented herein for the purposes of illustration and description only; it is not intended to be exhaustive or to be limited to the precise form disclosed.

Unless otherwise limited in the specific examples, the following definitions can be applied to the terms used throughout the specification.

The term “comprising” or “including” as used herein means that in addition to the described components, steps, and/or elements, the presence of one or more other components, steps, and/or elements is not excluded.

In the present invention, the terms “first layer board” and “upper plate” as used herein have the same meaning and can be used interchangeably.

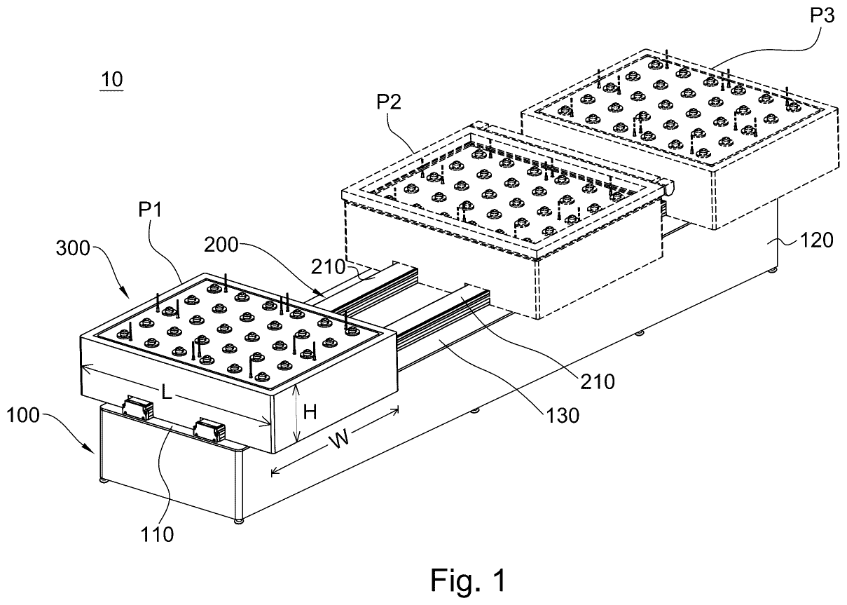

Please refer to FIG. 1, which shows a schematic diagram of a multi-layer board manufacturing device according to an embodiment of the present invention. The multi-layer board manufacturing device 1 of the present invention includes a base 100, a slide 200 and a multi-layer board operating platform 300, wherein the base 100 has a first end 110 and a second end 120; the slide 200 is configured on the base 100; and the multi-layer board operating platform 300 is configured on the slide 200 to translate between the first end 110 and the second end 120.

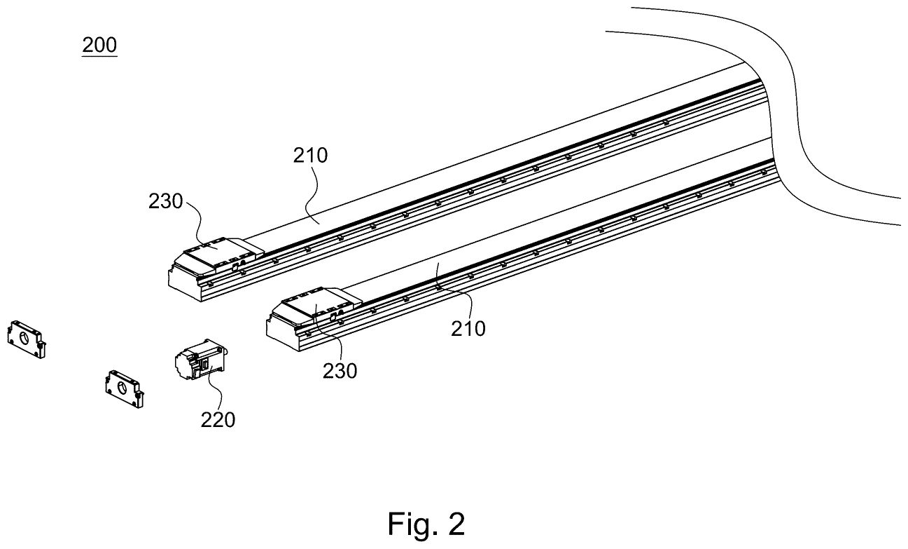

In order to enable the multi-layer board operating platform 300 to be translated to all operation areas, the base 100 is located at all of the operating areas, and thus the base 100 has a plurality of areas corresponding to the operating areas. For example, if there are three operation areas which are separated from each other by partition walls, the base 100 has three areas. A number of the areas and a length of the base 100 are not limited, and can be determined according to an actual space. The slide 200 is fixed on an upper surface 130 of the base 100, and a length of the slide 200 can be the same as or shorter than that of the base 100. Please refer to FIG. 2, which shows an exploded schematic diagram of the slide of the multi-layer board manufacturing device according to the embodiment of the present invention. The slide 200 includes two slide rails 210, a motor 220 and two sliding plates 230. The two sliding plates 230 are respectively configured on the two slide rails 210, and can slide on the two slide rails 210. The multi-layer board operating platform 300 is configured on the two sliding plates 230, as shown in FIG. 1. In another embodiment, a number of the slide rails is not limited, the slide rail can be a linear moving mechanism having only one slide rail or multiple slide rails, such as the slide rail being used with a timing belt or a gantry platform, which enables the multi-layer board operating platform 300 to be positioned on the base 100 rapidly and accurately. The motor 220 is configured on or in one of the two slide rails 210 to drive the two sliding plates 230 to slide on the two slide rails 210, and cause the multi-layer board operating platform 300 on the two sliding plates 230 to be linearly translated between the first end 110 and the second end 120 of the base 100, and located at one of the plurality of areas, such as one of the positions P1-P3 in FIG. 1. In the embodiment of the present invention, the motor 220 as shown in FIG. 2 can be a linear motor, a stepper motor or a servomotor.

In order to reduce a size of the multi-layer board operating platform 300, at least one small driving device is used in the present invention to drive the elevation of the positioning pins, and a controller is used to control the at least one small driving device to be simultaneously driven, to ensure that the positioning pins are synchronously elevated and precisely position controlled. The small driving device in the present invention can be any motor using direct current, i.e., a DC driving device. The DC driving device can be a thin motor that can be digitally controlled. A thin stepper motor is used as an example in this embodiment of the present invention. Therefore, in another embodiment, the thin stepper motor can also be replaced with a thin servomotor or a thin DC direct drive motor. Because the power of the DC motor can also be provided by a rechargeable battery in addition to the power cord, the multi-layer board operating platform 300 can be wirelessly charged at the first end 110 or the second end 120. Therefore, the multi-layer board operating platform 300 can be moved conveniently and freely on the slide rail 210 without the power cord. In another embodiment, at least one flexible power cord can be used as a power supply of the DC driving device.

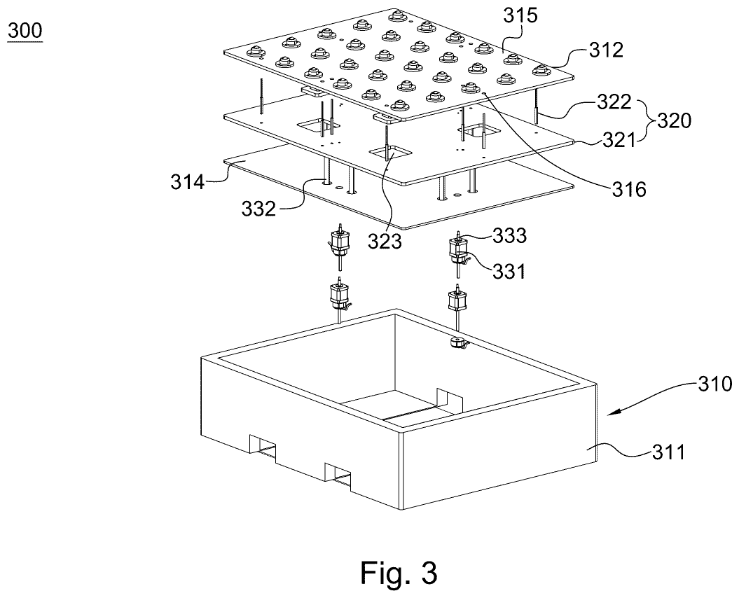

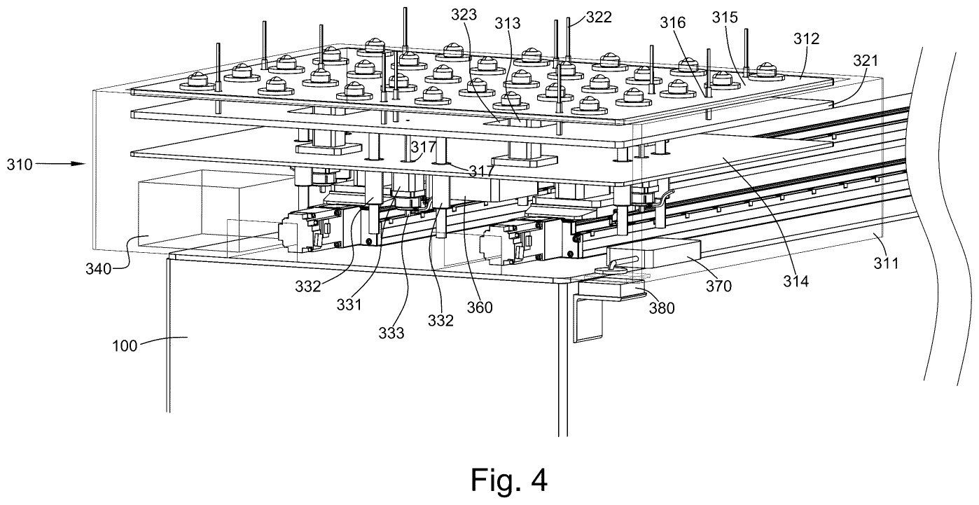

Please refer to FIGS. 3-4, which respectively show an exploded schematic diagram and a perspective schematic diagram of the multi-layer board operating platform of the multi-layer board manufacturing device according to the embodiment of the present invention. The multi-layer board operating platform 300 of the present invention includes a casing body 310, a positioning pin structure 320, a plurality of thin motor structures 330 and a controller 340, wherein the positioning pin structure 320, the plurality of thin motor structures 330 and the controller 340 are configured in the casing body 310, and the plurality of thin motor structures 330 are configured adjacent to the positioning pin structure 320 for driving an elevation of the positioning pin structure 320. The casing body 310 includes a shell 311, an upper plate 312, a binding post 313 and a lower plate 314, wherein the upper plate 311 covers the shell 311, the binding post 313 is configured between the upper plate 312 and the lower plate 314, and the upper plate 312 is connected to the lower plate 314 through the binding post 313. The upper plate 312 has an upper surface 315, and the upper surface 315 has a plurality of openings 316. The positioning pin structure 320 includes a carrying plate 321 and a plurality of positioning pins 322 configured on the carrying plate 321, wherein the plurality of positioning pins 322 respectively correspond to the plurality of openings 316 of the upper plate 312. The carrying plate 321 has a plurality of openings 323, and the binding post 313 connects the upper plate 312 and the lower plate 314 through the plurality of openings 323. Each of the plurality of thin motor structures 330 includes a thin motor 331 and a plurality of support axes 332, wherein the thin motor 331 and the plurality of support axes 332 are configured on the lower plate 314. The lower plate 314 has a plurality of openings 317, and the thin motor 331 has a driving shaft 333. The driving shaft 333 of the thin motor 331 and the plurality of support axes 332 of the thin motor structure 330 pass through the plurality of openings 317 of the lower plate 314 and abut a lower surface of the carrying plate 321. The upper plate 312 and the lower plate 314 are fixed with the shell 311, and the carrying plate 321 can be moved up and down in the casing body 310.

Therefore, when the plurality of thin motors 331 are driven upward, the driving shaft 333 and the plurality of support axes 332 push the entire carrying plate 321 to move upward, so that the plurality of positioning pins 322 on the carrying plate 321 are capable of telescopically passing through and sticking out from the plurality of openings 316 of the upper plate 312. Similarly, the plurality of thin motors 331 can drive the entire carrying plate 321 to move downward, so that the plurality of positioning pins 322 on the carrying plate 321 are lowered from the plurality of openings 316 of the upper plate 312. In the embodiment of the present invention, the thin motor 331 can be a thin stepper motor or a thin servomotor.

In the aforementioned embodiments, a number of the thin motor structures 330 of the present invention is at least 4, to ensure that the thin motors 331 have sufficient torque to drive the elevation of the positioning pin structure 320.

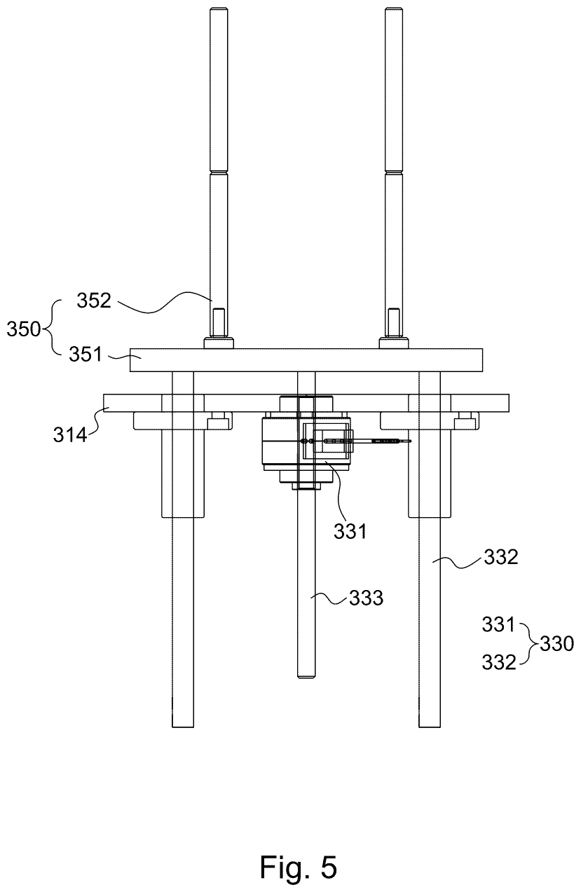

Please refer to FIG. 5, which shows a schematic diagram of a positioning pin structure of a multi-layer board operating platform according to a second embodiment of the present invention. The difference between the first embodiment and the second embodiment is that in the second embodiment, the multi-layer board operating platform 300 includes a plurality of positioning pin structures 350 configured in the casing body 310. Each of the plurality of positioning pin structures 350 includes a carrying plate 351 and 1 to 4 positioning pins 352 carried on the carrying plate 351, and each positioning pin 352 corresponds to one opening 316 of the upper plate 312. One thin motor structure 330 is correspondingly configured under each of the plurality of positioning pin structures 350. Similarly, each thin motor structure 330 includes a thin motor 331 and two support axes 332, and the thin motor 330 drives the positioning pin structure 350 thereabove. Therefore, when each thin motor 331 are driven upward, the driving shaft 333 and the plurality of support axes 332 push the carrying plate 351 thereabove to move upward, so that the 1 to 4 positioning pins 352 on the carrying plate 351 are capable of sticking out from the plurality of openings 316 of the upper plate 312. Similarly, each thin motor 331 can drive the carrying plate 351 thereabove to move downward, so that the 1 to 4 positioning pins 352 on the carrying plate 351 are lowered from the plurality of openings 316 of the upper plate 312.

According to the second embodiment above, a number of the positioning pin structures 350 is the same as that of the thin motor structure 330 (or the thin motor 331), and a number of the positioning pins 352 is 1 to 4 times that of the thin motor structure 330 (or the thin motor 331). Therefore, the number of the positioning pins can be adjusted according to the requirement, to ensure that the thin motor 331 has sufficient torque to drive the elevation of the positioning pin structure 350.

In another embodiment, all positioning pins can be carried by one carrying plate of the positioning pin structure, and one thin motor is configured under the positioning pin structure to drive the elevation of the positioning pin structure. Specifically, the multi-layer board operating platform 300 of the present invention can use only one thin motor to drive the elevation of the positioning pins.

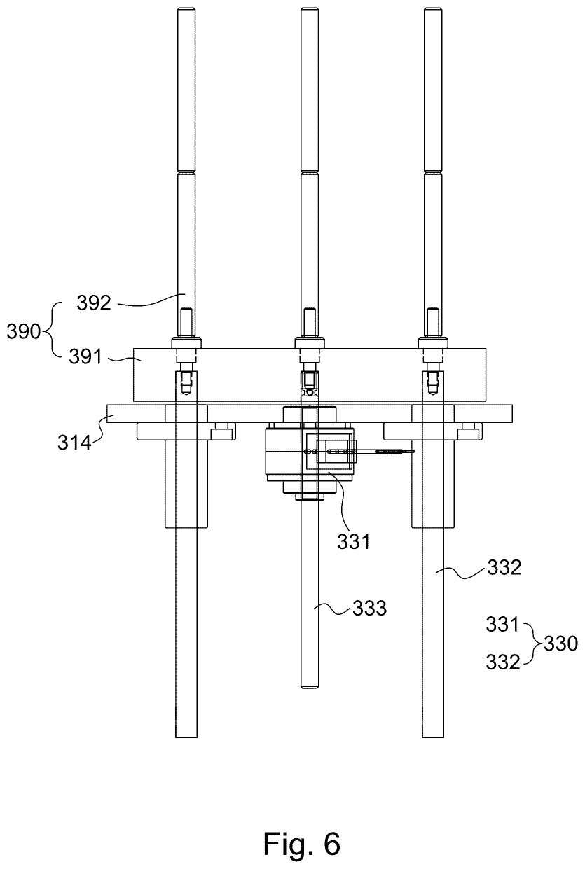

Please refer to FIG. 6, which shows a schematic diagram of a positioning pin structure of a multi-layer board operating platform according to a third embodiment of the present invention. The third embodiment is a variation of the second embodiment. In the third embodiment, the multi-layer board operating platform 300 can include a plurality of positioning pin structures 390 and a plurality of thin motor structures 330. Each of the plurality of positioning pin structures 390 includes a carrying plate 391 and at least one positioning pin 392. Each of the thin motor structure 330 includes a thin motor 331 and a plurality of support axes 332, wherein the thin motor 331 and the plurality of support axes 332 can connect to the at least one positioning pin 392 to drive the at least one positioning pin 392 directly. In the third embodiment, according to the number of the thin motor 331 and the plurality of support axes 332, each thin motor structure 330 can drive the elevation of 1 to 4 positioning pins 392.

According to all the embodiments above, in order to ensure that the positioning pin structures or the positioning pins can be elevated synchronously, the controller 340 of the multi-layer board operating platform 300 of the present invention is electrically connected to the plurality of thin motors 331, as shown in FIGS. 3-4. The controller 340 can control the plurality of thin motors 331 to operate simultaneously and to move precisely. Therefore, the controller 340 can ensure that the positioning pin structure or the plurality of positioning pins are synchronously elevated.

Because different areas can be completely isolated by baffles or walls, in order to allow the multi-layer board operating platform 300 to translate among different areas without interference from the power cords or cables, the multi-layer board operating platform 300 of the present invention uses a rechargeable battery as a power supply. Therefore, the multi-layer board operating platform 300 further includes a rechargeable battery 360 configured in the casing body 310, the rechargeable battery 360 is electrically connected to the plurality of thin motors 331 and the controller 340 for providing a power for an operation of the plurality of thin motor 331 and the controller 340. In the embodiments of the present invention, the multi-layer board operating platform 300 can include at least one rechargeable battery 360, and the rechargeable battery 360 can be a lithium battery, preferably, a 24V lithium battery.

In order to charge the rechargeable battery 360 conveniently and safely, the multi-layer board operating platform 300 of the present invention further includes a charging module 370 configured in the casing body 310, and the multi-layer board manufacturing device 10 further includes a wireless charging device 380 configured on an outer surface of the first end 110 of the base 100, as shown in FIG. 4. The charging module 370 is electrically connected to the rechargeable battery 360 for charging the rechargeable battery 360. When the multi-layer board operating platform 300 is moved to the first end 110, a position of the charging module 370 corresponds to a specific position of the wireless charging device 380, and the wireless charging device 380 inductively charges the rechargeable battery 360 through the charging module 370. The advantage of using the rechargeable battery 360 as the power supply is that the power cords or cables can be stored in the casing body 310, to reduce the interference and constraints of the power cords or cables.

In another embodiment, a flexible power cord connecting a power source can be used as the power supply in the multi-layer board operating platform 300 of the present invention. Therefore, the multi-layer board operating platform 300 further includes at least one flexible power cord (figure not shown) electrically connected to the plurality of thin motors and the controller for providing a power for an operation of the plurality of thin motors and the controller. Because the high flexibility the flexible power cord, it can be translated between the first end 110 and the second end 120 of the base 100 along with the multi-layer board operating platform 300 of the present invention.

According to the above, the plurality of thin motors 330 are used in the present invention to drive the elevation of the plurality of positioning pins 322, 352, 353, which causes a height of the multi-layer board operating platform 300 to be minimized to no large than 350 mm, preferably, no large than 300 mm. In an embodiment, a length (L) of the multi-layer board operating platform 300 is 600 mm, a width (W) of the multi-layer board operating platform 300 is 800 mm and a height (H) of the multi-layer board operating platform 300 is 300 mm, as shown in FIG. 1. A volume of the multi-layer board operating platform 300 is greatly reduced, which causes the multi-layer board operating platform 300 to be easily moved. In addition, the slide 200 enables the multi-layer board operating platform 300 to translate among different operating areas, which causes the operation of the stack-up of the board multi-layers to be more convenient. Because the multi-layer board operating platform 300 is minimized, the base 100 is needed to raise the multi-layer board operating platform 300, so that a position of the multi-layer board operating platform 300 is within an operating height range that is convenient for the operator.

In view of above, in the multi-layer board manufacturing device of the present invention, at least one thin motor is used in the multi-layer board operating platform to control the plurality of positioning pins to be elevated synchronously, and to minimize the multi-layer board operating platform. The multi-layer board operating platform is further configured on the slide fixing on the base, so that the multi-layer board operating platform is translatable to be located at different areas based on the stack-up step of the board multi-layers. The different areas, including, for example, a clean area, an intermediate layer stacking area and a dust-removing area, are isolated from one another according to their cleanliness level, wherein the cleanliness level of the clean area, the intermediate layer stacking area and the dust-removing area is in decreasing order. The copper foil sheets and the steel plate are stacked at the clean area, the PP layers are stacked at the intermediate layer stacking area, and the dust or impurities can be removed at the dust-removing area. Therefore, when the stack-up step is performed, the multi-layer board operating platform can be translated on the base to be located at the clean area, the intermediate layer stacking area or the dust-removing area to stack different layers and remove the dust. Accordingly, the copper foil sheets and the steel plate can be kept absolutely clean to prevent the short circuits and open circuits caused by pits and dents from forming on surfaces of the copper foil sheets, and the yield rate of circuit board circuit products can be greatly improved.

According to experiments, the present invention can be applied to the planning of the above-mentioned zoned manufacturing, which improves the yield rate of the PCB multilayer board manufacturing process from about 80% to a high-quality level of about 95%, which significantly reduces the manufacturing costs of industries.

Although the present application has been described with reference to certain exemplary embodiments thereof, it can be understood by those skilled in the art that a variety of modifications and variations may be made to the present application without departing from the spirit or scope of the present application defined in the appended claims, and their equivalents.

What is claimed is:

1. A multi-layer board manufacturing device, comprising:
a base having a first end and a second end;
a slide configured on the base; and
a multi-layer board operating platform configured on the slide to translate between the first end and the second end, wherein the multi-layer board operating platform comprises:
a casing body having an upper surface, wherein the upper surface has a plurality of openings;
a positioning pin structure configured in the casing body and having a plurality of positioning pins, wherein the plurality of positioning pins respectively correspond to the plurality of openings and are capable of telescopically sticking out from the plurality of openings;
at least one DC driving device configured in the casing body and adjacent to the positioning pin structure for driving an elevation of the positioning pin structure; and
a controller configured in the casing body and electrically connected to the at least one DC driving device for controlling the at least one DC driving device to simultaneously drive a synchronized elevation of the positioning pin structure.

2. The multi-layer board manufacturing device as claimed in claim 1, wherein the multi-layer board operating platform further comprises a power supply electrically connected to the at least one DC driving device and the controller for providing a power for an operation of the multi-layer board operating platform.

3. The multi-layer board manufacturing device as claimed in claim 2, wherein the power supply comprises:
a rechargeable battery configured in the casing body and electrically connected to the at least one DC driving device and the controller for providing the power to the at least one DC driving device and the controller; and
a charging module configured in the casing body and electrically connected to the rechargeable battery for charging the rechargeable battery.

4. The multi-layer board manufacturing device as claimed in claim 3, further comprising a wireless charging device configured on an outer surface of the first end of the base, wherein when the multi-layer board operating platform is moved to the first end, a position of the charging module corresponds to a specific position of the wireless charging device, where the wireless charging device inductively charges the rechargeable battery through the charging module.

5. The multi-layer board manufacturing device as claimed in claim 2, wherein the power supply comprises at least one flexible power cord electrically connected to the at least one DC driving device.

6. The multi-layer board manufacturing device as claimed in claim 1, wherein the slide comprises a motor to move the multi-layer board operating platform between the first end and the second end.

7. The multi-layer board manufacturing device as claimed in claim 1, wherein the at least one DC driving device is a thin motor, and the thin motor is a thin stepper motor or a thin servomotor.

8. A multi-layer board operating platform, wherein the multi-layer board operating platform is to be configured on a slide of a base to translate on the base, and the multi-layer board operating platform comprises:
a casing body;
a first layer board configured on the casing body and having a plurality of openings;
a positioning pin structure configured in the casing body and comprising a plurality of positioning pins, wherein the plurality of positioning pins are capable of telescopically passing through the plurality of openings, respectively; and
at least one DC driving device configured adjacent to the positioning pin structure for driving an elevation of the positioning pin structure.

9. The multi-layer board operating platform as claimed in claim 8, further comprising:
a controller configured in the casing body and electrically connected to the at least one DC driving device for controlling the at least one DC driving device to simultaneously drive a synchronized elevation of the positioning pin structure; and
a power supply electrically connected to the at least one DC driving device and the controller for providing a power for an operation of the multi-layer board operating platform.

10. The multi-layer board operating platform as claimed in claim 9, wherein the power supply comprises:
a rechargeable battery configured in the casing body and electrically connected to the controller and the at least one DC driving device for providing the power to the controller and the at least one DC driving device; and
a charging module configured in the casing body and electrically connected to the rechargeable battery for charging the rechargeable battery.

11. The multi-layer board operating platform as claimed in claim 9, wherein the power supply comprises at least one flexible power cord electrically connected to the at least one DC driving device.

12. The multi-layer board operating platform as claimed in claim 8, wherein the positioning pin structure further comprises a carrying plate, the plurality of positioning pins are configured on the carrying plate, and a number of the at least one DC driving device is at least 4.

13. The multi-layer board operating platform as claimed in claim 8, wherein the positioning pin structure further comprises a plurality of positioning pin sub-structures, each of the plurality of positioning pin sub-structures comprises a carrying plate and 1 to 4 positioning pins, the multi-layer board operating platform comprises a plurality of DC driving devices, and each of the plurality of DC driving devices is correspondingly configured under each of the plurality of positioning pin sub-structures.

14. The multi-layer board operating platform as claimed in claim 8, wherein a number of the plurality of positioning pin sub-structures is the same as that of the plurality of DC driving devices, and a number of the plurality of positioning pins is 1 to 4 times that of the plurality of DC driving devices.

15. A multi-layer board operating platform adapted to be configured on a slide slidable on a base, comprising:
a casing body having an upper surface, wherein the upper surface has a plurality of openings;
a positioning pin structure configured in the casing body and comprising a plurality of positioning pins capable of telescopically passing through the plurality of openings, respectively; and
a driving device configured in the casing body and adjacent to the positioning pin structure for driving an elevation of at least one of the plurality of positioning pins.

16. The multi-layer board operating platform as claimed in claim 15, wherein the driving device is a DC driving device, and a height of the casing body is no large than 350 mm.

17. The multi-layer board operating platform as claimed in claim 16, wherein the base is configured to have a plurality of areas, and the multi-layer board operating platform is translatable to be located at one of the plurality of areas.

18. The multi-layer board operating platform as claimed in claim 16, further comprising a rechargeable battery configured in the casing body and electrically connected to the DC driving device, wherein the rechargeable battery is charged by a wireless charging device configured on the base.

19. The multi-layer board operating platform as claimed in claim 16, further comprising a flexible power cord electrically connected to the DC driving device.

20. The multi-layer board operating platform as claimed in claim 15, wherein all cables of the multi-layer board operating platform are stored in the casing body.
